(19) United States
(12) Patent Application Publication
(10) Pub. No.: US 2023/0408926 A1
(43) Pub. Date: Dec. 21, 2023

(54) PLASMA-ACTIVATED LIQUIDS

(71) Applicant: The Board of Trustees of the University of Illinois, Urbana (IL)

(72) Inventors: David RUZIC, Urbana, IL (US); Mohan SANKARAN, Urbana, IL (US); Christian WILLIAMS, Urbana, IL (US)

(73) Assignee: The Board of Trustees of the University of Illinois, Urbana, IL (US)

(21) Appl. No.: 18/035,865

(22) PCT Filed: Nov. 8, 2021
(86) PCT No.: PCT/US21/58399

§ 371 Date: May 8, 2023

Related U.S. Application Data
(60) Provisional application No. 63/111,577, filed on Nov. 9, 2020.

(51) Int. Cl. G03F 7/42; G03F 7/32; H01L 21/027; H01L 21/02; H01L 21/311

(52) U.S. Cl. CPC G03F 7/427; G03F 7/325; H01L 21/0274; H01L 21/0206; H01L 21/31111; H01L 21/31144

(57) ABSTRACT

Plasma-Activated liquids and methods of using the same are described. In one aspect, a method of manufacturing an integrated circuit includes activating a photolithography liquid with a plasma; and treating a device component with the activated photolithography liquid. In one example, the photolithography liquid is a photoresist. Activating the photoresist liquid may impart reactive species to the photoresist.

### CROSS-REFERENCE TO RELATED APPLICATIONS

This application claims the benefit of priority to U.S. Provisional Patent Application No. 63/111,577, filed Nov. 9, 2020, which is hereby incorporated by reference in its entirety.

### BACKGROUND OF INVENTION

Integrated circuit manufacturing requires the use of specialized chemicals at several key steps. An important processing step involves exposing photoresist to electromagnetic radiation, thereby causing a chemical change in the photoresist such that a subsequent step and chemical application of developer can remove the material, and only the material, that has been exposed to the light, or the material and only the material that has not been exposed to light. This creates a pattern on the layer beneath which then can be etched. After the etching, another step, often using a plasma, called ashing removes the remaining photoresist material without harming the underlying layers. One problem of conventional chip manufacturing involves residue still on the chip after the ashing step. Therefore, another chemical step is needed after the ashing step. A cleaning solution is often used to remove that residue.

Recently, integrated circuit manufacturing lithography has undergone a dramatic technology transition. The newest and smallest chips are now using extreme ultra-violet (EUV) as the light source for lithography. EUV lithography utilizes wavelengths of electromagnetic radiation around 13.5 nm (˜100 eV photons) instead of the more conventional 193 nm (˜5 eV photons) wavelength. One limitation of the current technology is the conventional photoresist is not sensitive enough. The current level needed of energy to expose the pattern in conventional photoresist is approximately 40 mJ/cm². However, in order to achieve the desired throughput in high-volume manufacturing while minimizing the line-edge roughness of the features created via photolithography, the industry has set a goal of developing photoresist that can be exposed using electromagnetic radiation intensities that impart 10 to 15 mJ/cm² to the photoresist.

Thus, while the industry is rapidly adopting EUV in the exposure step, the technology of the other steps, including the photoresist chemistry, as well as that of the developer and cleaning solutions have not yet caught up with the EUV sea change. The chemicals involved are still essentially the same as have been used for years in conventional 193 nm lithography, and they are not performing as well as needed. Therefore, it can be seen that improved photoresist, developer, and the cleaning solutions are needed.

### SUMMARY OF THE INVENTION

In one aspect of the present invention, a plasma is used to “activate” chemicals, for example, photolithography chemicals, before their use. Plasma activation may create several long-lived species in the liquid, for example, and without being bound by theory: (1) free radicals, (2) solvated electrons, and/or (3) metastable compounds otherwise difficult to synthesize.

In some embodiments, the process utilizes an atmospheric pressure plasma to act on the chemical or a component of the ultimate chemical mixture to activate it. Then the chemical mixtures may exhibit enhanced efficacy as compared to the same mixture left untreated by plasma.

In some embodiments, a plasma-activated liquid comprises a non-aqueous liquid medium; and at least one reactive species produced via contacting the surface of the non-aqueous liquid medium with a plasma. In some embodiment, the at least one reactive species includes free radicals, solvated electrons, or both.

In one embodiment, the plasma activated liquid includes not greater than 5 wt. % water. In one embodiment, the plasma activated liquid includes not greater than 3 wt. % water. In one embodiment, the plasma activated liquid includes not greater than 2 wt. % water. In one embodiment, the plasma activated liquid includes not greater than 1 wt. % water. In one embodiment, the plasma activated liquid includes not greater than 0.1 wt. % water. In one embodiment, the plasma activated liquid includes not greater than 0.01 wt. % water. In one embodiment, the plasma activated liquid includes not greater than 0.001 wt. % water.

In some embodiments, the plasma activated liquid comprises free radicals, solvated electrons, or both. In some embodiments, the plasma activated liquid comprises a photolithography liquid. In some embodiments, the photolithography liquid is a photoresist liquid. In some embodiments, the photolithography liquid is a developer liquid. In some embodiments, the photolithography liquid is a cleaning solution liquid.

In some embodiments, the plasma-activated liquid comprises a plurality of molecules wherein each of the plurality of molecules comprises a carbon backbone. In some embodiments, each of the plurality of molecules comprises at least one covalent bond joining an acid group, directly or indirectly, to the carbon backbone.

In some embodiments, the plasma-activated liquid comprises or more ionic species to stabilize free radicals and/or solvated electrons in the plasma-activated liquid.

In one aspect, a method of manufacturing an integrated circuit comprises activating a photolithography liquid with a plasma; and treating a device component with the activated photolithography liquid. In some embodiments, the activating step comprises bringing the photolithography liquid into contact with a plasma.

In some embodiments, the activating step comprises creating free radicals, solvated electrons, or both in the photolithography liquid. In some embodiments, the activating step comprises weakening at least one covalent bond in one or more molecules of the photolithography liquid.

In some embodiments, the activating step comprises weakening at least one covalent bond in each of a plurality of solvated molecules of the photolithography liquid, wherein each of the plurality of molecules comprises a carbon backbone. In some embodiments, the at least one covalent bond joins an acid group, directly or indirectly, to the carbon backbone. In some embodiments, the activating step comprises stabilizing the free radicals and/or solvated electrons via cations.

In some embodiments, the activating step comprises stabilizing the free radicals and/or solvated electrons via one or more functional groups supported by the carbon backbone. In some embodiments, the one or more functional groups comprises cationic functional groups. In some embodiments, the one or more functional groups comprises anionic functional groups.

In some embodiments, the photolithography liquid is selected from the group consisting of: a photoresist liquid, a developer liquid, and a cleaning solution liquid. In some embodiments, the activating step occurs prior to the treating step. In some embodiments, the treating step includes contacting the device component with activated photolithography liquid. In some embodiments, the device component comprises a semiconductor wafer.

In one aspect, the photolithography liquid may comprise a photoresist liquid. In some embodiments, the photolithography liquid comprises a positive photoresist. In some embodiments, the photolithography liquid comprises a negative photoresist.

In some embodiments, the method comprises hardening the photoresist liquid into a solid layer of photoresist on the semiconductor wafer, wherein after the hardening step, free radicals and/or solvated electrons produced via the contacting step are trapped in the solid layer of photoresist.

In some embodiments, the method comprises exposing the solid layer of photoresist to a pattern of electromagnetic radiation, and in response to the exposing step, releasing at least some of the electrons of the trapped free radicals and/or solvated electrons, thereby cleaving covalent or ionic bonds in the solid layer of photoresist.

In some embodiments, the method comprises in response to the releasing step, freeing acid groups in the solid layer of photoresist. In some embodiments, the electromagnetic radiation comprises extreme ultraviolet radiation. In some embodiments, the electromagnetic radiation exhibits an intensity peak in a wavelength range of 13.3 to 13.7 nm.

In one aspect, the plasma may be an atmospheric pressure plasma. In some embodiments, the contacting step occurs in a controlled gas environment at reduced pressures. In some embodiments, the plasma is formed via a D.C. current. In some embodiments, the plasma is a surface wave plasma. In some embodiments the plasma is formed with an RF source or a microwave source.

In one aspect a method of manufacturing an integrated circuit comprises the steps of coating at least a portion of a surface device component with a photoresist liquid, hardening the photoresist liquid into a solid layer of photoresist on the wafer, exposing the solid layer of photoresist to a pattern of electromagnetic radiation, contacting the photoresist with a developer liquid to develop a corresponding pattern in the photoresist, etching the wafer to transfer the pattern from the photoresist to the layer below the photoresist layer, ashing the remaining photoresist, and cleaning the wafer with a cleaning solution liquid to remove photoresist residue from the wafer. Additionally, at least one of the following steps may be performed: activating the photoresist liquid or a component of the photoresist liquid with a plasma; activating the developer liquid or a component of the developer liquid with a plasma; and/or activating the cleaning solution liquid or a component of the cleaning solution liquid with a plasma.

In some embodiments, the method may comprise activating the photoresist liquid with the plasma prior to or concomitant with the coating step. In some embodiments, the method may comprise activating the developer liquid with the plasma prior to or concomitant with the contacting step. In some embodiments, the method may comprise activating the cleaning solution with the plasma prior to or concomitant with the cleaning step.

In one aspect of the present invention, a method of manufacturing an integrated circuit may comprise coating at least a portion of a surface device component with a photoresist liquid, hardening the photoresist liquid into a solid layer on the wafer, exposing the photoresist to electromagnetic radiation, applying developer liquid to remove the exposed photoresist, prior to or concomitant with the applying step, activating the developer liquid via a plasma thereby introducing free radicals and/or solvated electrons into the developer liquid, etching the exposed parts of the wafer, ashing the remaining photoresist, and removing photoresist residue with a liquid cleaning solution.

In one aspect of the present invention, a method of manufacturing an integrated circuit comprises, coating at least a portion of a surface device component with a photoresist liquid, hardening the photoresist liquid into a solid layer on the wafer, exposing the photoresist to electromagnetic radiation, applying developer liquid to remove the exposed photoresist, etching the exposed parts of the wafer, ashing the remaining photoresist, removing photoresist residue with a liquid cleaning solution; and prior to or concomitant with the removing step, activating the liquid cleaning solution via a plasma thereby introducing free radicals and/or solvated electrons into the liquid cleaning solution.

In some embodiments, as an alternative to ashing the device component, the remaining photoresist may be removed via a stripper liquid. The stripper liquid may optionally be plasma activated via the methods of plasma liquid activation described herein.

In some embodiments, the method comprises mixing a first component with a second component to form the liquid cleaning solution, for example, prior to the removing step. In some embodiments, the activating step comprises activating the first component with a plasma, for example, prior to the mixing step. In some embodiments, the method comprises acting on a component of one of the photolithography chemicals with a plasma, then mixing that components with other components to make that chemical.

In one embodiment, a method of manufacturing an integrated circuit comprises coating at least a portion of a surface device component with a photoresist liquid, hardening the photoresist liquid into a solid layer on the wafer, exposing the photoresist to electromagnetic radiation, applying developer liquid to remove the exposed photoresist, etching the exposed parts of the wafer, ashing the remaining photoresist, and removing photoresist residue with a liquid cleaning solution. Prior to or concomitant with the coating step, the photoresist liquid, or a component of the photoresist liquid may be activated via a plasma thereby introducing free radicals and/or solvated electrons into the photoresist liquid or a component of the photoresist liquid.

In one embodiment, a method of manufacturing an integrated circuit comprises coating at least a portion of a surface device component with a photoresist liquid, hardening the photoresist liquid into a solid layer on the wafer, exposing the photoresist to electromagnetic radiation, applying developer liquid to remove the exposed photoresist, etching the exposed parts of the wafer, ashing the remaining photoresist, and removing photoresist residue with a liquid cleaning solution. Prior to or concomitant with the applying step, the developer liquid, or a component of the developer liquid may be activated via a plasma thereby introducing free radicals and/or solvated electrons into the developer liquid or a component of the developer liquid.

In one embodiment, a method of manufacturing an integrated circuit comprises coating at least a portion of a surface device component with a photoresist liquid, hardening the photoresist liquid into a solid layer on the wafer, exposing the photoresist to electromagnetic radiation, applying developer liquid to remove the exposed photoresist, etching the exposed parts of the wafer, ashing the remaining photoresist, and removing photoresist residue with a liquid cleaning solution. Prior to or concomitant with the removing step, the liquid cleaning solution, or a component of the liquid cleaning solution may be activated via a plasma thereby introducing free radicals and/or solvated electrons into the liquid cleaning solution or a component of the liquid cleaning solution.

Without wishing to be bound by any particular theory, there may be discussion herein of beliefs or understandings of underlying principles relating to the devices and methods disclosed herein. It is recognized that regardless of the ultimate correctness of any mechanistic explanation or hypothesis, an embodiment of the invention can nonetheless be operative and useful.

### BRIEF DESCRIPTION OF THE DRAWINGS

FIG. 1 is a schematic diagram of a plasma activation apparatus useful in the manufacture of some embodiments of the present invention.

FIG. 2 is a flowchart illustrating a method of manufacturing an integrated circuit and showing where plasma-activation steps may be introduced.

FIG. 3 is an illustration of several intermediate steps of the method of FIG. 2.

FIGS. 4A-B are charts of current and voltage vs tie of an AC remote plasma jet used to pretreat a photoresist liquid in accordance with one embodiment of the invention. FIG. 4A shows the plasma jet in a “low” power mode, having an average current of 1.2 mA. FIG. 4B shows the plasma jet in a “high” power mode, having an average current of 1.5 mA.

FIGS. 4C-D are photographs of the plasma jet of FIGS. 4A-B respectively

FIG. 5 is a photograph of a side by side comparison of a plasma activated photo resist after being exposed and developed (right) compared with a control photoresist (no plasma treatment; left) after both being exposed to light for 5 seconds and developed under the same conditions.

FIG. 6A is a photograph of a second side by side comparison of a plasma activated photoresist after being exposed and developed (right) compared with a control photoresist (no plasma treatment; left) after both were exposed for 3 seconds and developed under the same conditions.

FIG. 6B is a photograph of a second control photoresist (no plasma treatment) which was subjected to gas flow in order to rule out potential evaporation effects.

FIG. 7A is a photograph of a side by side comparison of a plasma activated photoresist after being exposed and developed (right) compared with a control photoresist (no plasma treatment; left) after both were exposed for 4 seconds and developed under the same conditions.

FIG. 7B is a photograph of a side by side comparison of a plasma activated photoresist after being exposed and developed (right) compared with a control photoresist (no plasma treatment; left) after both were exposed for 5 seconds and developed under the same conditions.

FIG. 8 is a schematic diagram of one embodiment of a pulsed plasma apparatus useful for plasma treatments in accordance with some embodiments of the present disclosure.

FIG. 9A is a schematic diagram of a second embodiment of a pulsed plasma apparatus useful for plasma treatments in accordance with some embodiments of the present disclosure.

FIG. 9B is a graph showing the output of the pulsed plasma apparatus of FIG. 9A.

FIG. 10 is a schematic illustration of a method of manufacturing an integrated circuit in accordance with the embodiment of FIGS. 6-8.

### STATEMENTS REGARDING CHEMICAL COMPOUNDS AND NOMENCLATURE

In general, the terms and phrases used herein have their art-recognized meaning, which can be found by reference to standard texts, journal references and contexts known to those skilled in the art. The following definitions are provided to clarify their specific use in the context of the invention.

As used herein, “a plasma-activated liquid” is a liquid (e.g., a solvent, solution, mixture, suspension, slurry, emulsion, among others) that has been altered, via a plasma, to have increased reactivity as compared to a sample of the same starting liquid that has not been treated with a plasma. In this regard, a plasma activation of a liquid may introduce reactive species, such as free radicals, solvated electrons, or other stable/metastable reactive species, to the liquid. Plasma-activated liquids may include mixtures of plasma-activated liquids with non-activated liquids.

As used herein, “a non-aqueous liquid medium” is a liquid medium that is less than half water by weight. In some embodiments, a non-aqueous liquid medium may comprise not greater than 5 wt. % water. In some embodiments, a non-aqueous liquid medium may comprise not greater than 3 wt. % water. In some embodiments, a non-aqueous liquid medium may comprise not greater than 2 wt. % water. In some embodiments, a non-aqueous liquid medium may comprise not greater than 1 wt. % water. In some embodiments, a non-aqueous liquid medium may comprise not greater than 0.1 wt. % water. In some embodiments, a non-aqueous liquid medium may comprise not greater than 0.01 wt. % water. In some embodiments, a non-aqueous liquid medium may comprise not greater than 0.001 wt. % water.

As used herein, “a reactive species” means a plurality of identical atoms, molecules, ions, or radicals having a tendency to react chemically.

As used herein, a “photolithography liquid” is a liquid used in the production of integrated circuits. Photolithography liquids include: liquids used to prepare device components (e.g., semiconductor wafers) for the photolithography process; liquids used in the photolithography process; and liquids used after the photolithography process to remove residue and clean the device component. Examples of photolithography liquids include photoresist liquids, developer liquids, and cleaning solution liquids.

As used herein, “photoresist liquid” is a liquid comprising a light-sensitive material, e.g. a liquid resin, used in photolithography to form a light sensitive photoresist layer on a surface of a device component. The layer of photoresist may then be exposed to a pattern of electromagnetic radiation, e.g., via a photomask, to pattern the photoresist. In some embodiments, the photoresist liquid is configured to harden into a solid layer on the surface. In some embodiments, the photoresist liquid is configured to form a layer of positive photoresist. In some embodiments, the photoresist liquid is configured to form a layer of negative photoresist.

As used herein, “a developer liquid” is a liquid configured to remove a portion of the photoresist layer in order to pattern the photoresist. Developer liquid is generally utilized after the photoresist has been exposed to a pattern of electromagnetic radiation. For a positive photoresist, the developer liquid may remove the portion of photoresist that was exposed to electromagnetic radiation. For a negative photoresist, the developer liquid may remove the portion of the photoresist that was not exposed to electromagnetic radiation.

As used herein, “a cleaning solution liquid” is a liquid configured to remove residue from a device component, for example, after ashing the photoresist. Cleaning solution liquid may also sometimes be referred to as “thinner liquid”.

As used herein, “a stripper liquid” is a liquid configured to remove the remaining photoresist after etching a pattern into a surface of a device component.

As used herein, “extreme ultraviolet radiation” is electromagnetic radiation having a wavelength from 124 nm down to 2 nm. In some embodiments, the extreme ultraviolet radiation has an intensity peak in a wavelength range of 13.3 to 13.7 nm. In some embodiments, the extreme ultraviolet radiation has an intensity peak at about 13.5 nm.

As used herein, “a controlled gas environment” is a closed environment in which at least one of pressure, temperature, and/or gas composition are controlled.

As used herein, “a device component” is a component, or a piece thereof, of an electrical circuit. Examples of device components include capacitors, diodes, resistors, integrated circuits or constitution parts thereof, e.g., semiconductor wafers which may include oxide layers and/or metal layers.

### DETAILED DESCRIPTION OF THE INVENTION

In the following description, numerous specific details of the devices, device components and methods of the present invention are set forth in order to provide a thorough explanation of the precise nature of the invention. It will be apparent, however, to those of skill in the art that the invention can be practiced without these specific details.

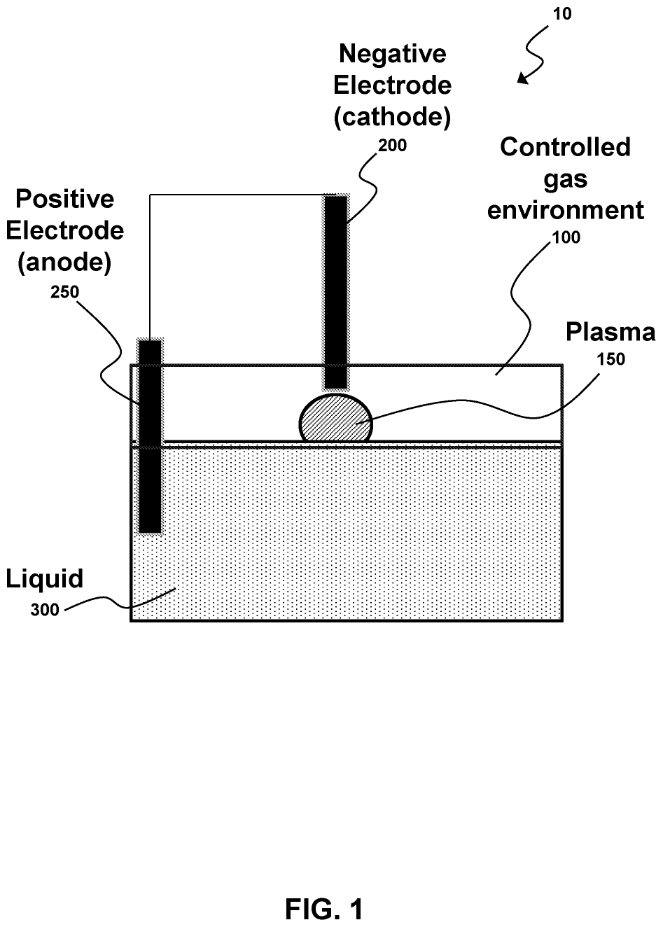

FIG. 1 is a schematic diagram of a plasma activation apparatus 10 useful in the manufacture of some embodiments of the present invention. Apparatus 10 includes a controlled gas environment 100, a cathode 200, an anode 250 and plasma 150. The Plasma 150 may contact the surface of the non-aqueous liquid 300. As a result of the contact with the plasma 150, the plasma may activate the liquid 300. For example, the plasma 150 may impart free radicals, solvated electrons, and or other metastable reactive species in the liquid 300. Without wishing to be bound by theory, it is believed that the electrons exist for a short time as free electrons in the liquid, alter chemical bonds and then those changes in the chemical bonds become stabilized by dipoles of a polar molecules and/or ions within the liquid 300.

In the illustrated embodiment, the plasma 150 may be a DC plasma generated by anode 250 and cathode 200. The controlled gas environment 100 may be controlled to a pressure that is at or near atmospheric pressure. The distance between the plasma and the liquid may be approximately 1 mm. In some embodiments, the plasma may be a plasma generated by a dielectric barrier discharge. In some embodiments, the plasma may be a radio-frequency (rf) plasma.

In the illustrated embodiment, the anode 250 is submerged or partially submerged in the liquid 300. In alternative embodiments, the anode may be the liquid itself, or a conductive plate below the liquid. In further alternative embodiments, the apparatus may comprise a plurality of plasma jets striking the liquid. The plurality of plasma jets may comprise one or more capillaries and/or one or more slot shaped electrodes. In some embodiments, the gas within the controlled gas environment comprises an inert gas. In some embodiments the controlled gas environment may be configured to deliver one or more gaseous chemical compounds via a bubbler, atomizer or evaporator. In some embodiments, the plasma may be a surface wave plasma.

In some embodiments, additionally or alternatively to the electrodes, the apparatus may include a nozzle disposed under the surface of the liquid to introduce a gas into the liquid. Al electric current may flow though the nozzle to create plasma in the gas as it is introduced into the liquid.

### Example DBD Plasma Conditions

| | |
|---|---|
| Gas flow rate (ml/min) | 500-1500 |
| Frequency (kHz) | 10-40 |
| Peak to Peak Voltage (kV) | 5-10 |
| Plasma exposure Time (minutes) | 30-120 |

In some embodiments, the controlled gas environment may be controlled to a pressure that is above atmospheric pressure. In some embodiments, the controlled gas environment may be controlled to a pressure that is below atmospheric pressure.

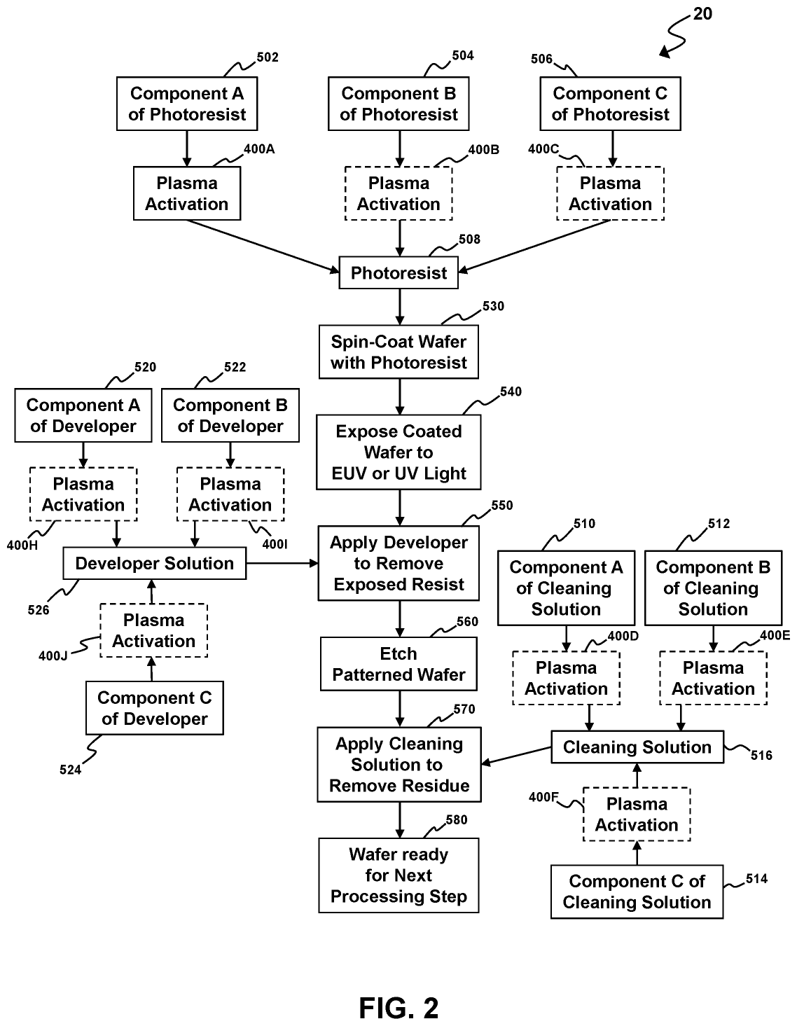

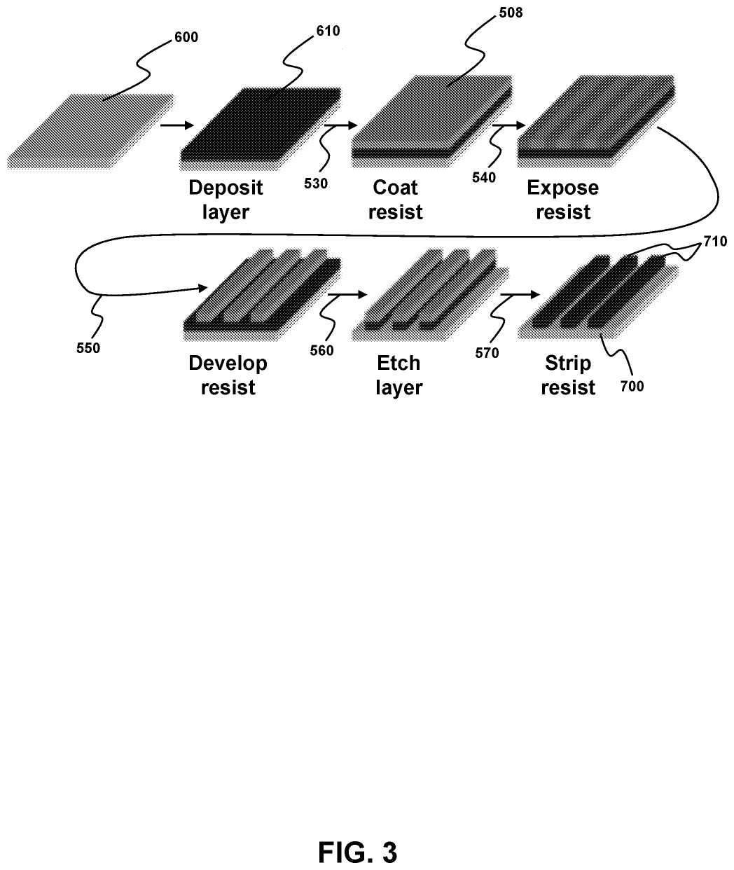

FIG. 2 is a flowchart illustrating a method of manufacturing an integrated circuit. FIG. 3 is an illustration of several intermediate products of the method of FIG. 2 In the illustrated method 20 of FIGS. 2-3, liquid component A 502 is mixed with component B 504 and component C 506 to form photoresist liquid 508. In other examples, any number of components may be mixed to form the photoresist liquid. Before mixing, component A is plasma-activated in step 400A. Thus, one or more reactive species may be imparted to component A. Optionally, components B and/or C may be plasma activated as well via optional steps 400B and 4000. In other examples, the photoresist liquid may be mixed prior to the plasma-activation step(s).

Next, a device component 600, such as a wafer, is provided. Optionally, the wafer may comprise at least one layers 610. The layer(s) 610 comprise at least one surface. In one embodiment, the at least one surface is a surface of an oxide layer of the wafer. In one embodiment, the at least one surface is a surface of a metal layer of the wafer. In one embodiment, the at least one surface is a surface of a silicon layer of the wafer. The layer 610 is spin coated with liquid photoresist in step 530 to form photoresist coating 508. The photoresist coating 508 may then be hardened into a solid layer of photoresist, for example via drying at elevated temperature. The layer of photoresist may cover at least one surface of the wafer. At least some of the reactive species, for example, free radicals and/or solvated electrons from the plasma activation step 400A (and optionally 400B and 400C) trapped in the coating 508 and may persist in their reactive form for a period of time.

Next, the coated device component is exposed to a pattern of electromagnetic radiation, for example, via a photomask at step 540. In one embodiment, the electromagnetic radiation is EUV radiation. In another embodiment, the electromagnetic radiation is UV radiation. In one aspect, the trapped reactive species in the coating 508 may impart enhanced photoreactivity to the photoresist. Thus, in some embodiments, the plasma-activated photoresist may allow the use of electromagnetic radiation having lower total energy per unit area during the exposure step. In this regard, line-edge roughness of the resulting features 710 in layer 610 may be improved.

In parallel, a developer liquid may be prepared by mixing component A 520 with component B 522 and component C 524. In other examples, any number of components may be mixed to form the developer liquid 526. Optionally, components A, B and/or C 520, 522, 524 may be plasma activated via optional steps 400H, 400I, 400J, thus imparting reactive species to the developer liquid 526.

The exposed device component is then developed 550 with developer liquid 526 to remove exposed photoresist and create features in the photoresist layer according to the photomask. In those embodiments where the developer liquid 526 is plasma activated, the reactive species in the developer liquid 526 may enhance the efficacy of the developer liquid.

Next, the patterned wafer may be etched in step 560 to transfer the photomask pattern from coating 508 to layer 610. In parallel, a cleaning solution (or thinning liquid) 516 may be prepared by mixing component A 510 with component B 512 and component C 514. In other examples, any number of components may be mixed to form the cleaning solution liquid 516. Optionally, components A, B and/or C 510, 512, 514 may be plasma activated via optional steps 400D, 400E, 400F, thus imparting reactive species to the cleaning solution liquid 516.

After the etching step 560, in some embodiments, the remaining photoresist may be removed via plasma ashing. In other embodiment, the remaining photoresist may be removed via chemical stripping with a stripper liquid. The stripper liquid, and/or components thereof, may be plasma activated via the methods disclosed herein, thus imparting reactive species to the stripper liquid. The plasma-activated stripper liquid may exhibit enhanced efficacy.

The cleaning solution liquid 516 may then be applied to the device component 600 to remove residue of the photoresist. In those embodiments where the cleaning solution liquid 516 is plasma activated, the reactive species in the cleaning solution liquid 516 may enhance the efficacy of the cleaning solution liquid.

At step 580, the patterned and cleaned device component 700 may then be ready for the next processing step

The invention can be further understood by the following non-limiting examples.

### Example 1: Plasma-Activated Photoresist Liquid

A conventional positive photoresist is provided. The photoresist comprises four components: the matrix or base material (resin), the sensitizer which is the photoactive compound (PAC) which also includes acid generating groups, the quencher which can scavenge excess acid, and solvents to adjust the viscosity. The photoresist is a chemically activated resist (CAR). A photon hits a certain bond in the substance and an acid is released. That acid then in turn unleashes more acid groups. Where the acid has taken effect, it breaks up the polymer and monomer chains so that the developer can wash those away. Quenchers remove acid groups to maintain a balance.

The photoresist is plasma activated via the apparatus of FIG. 1, applied to a wafer and exposed to EUV. The exposed wafer is developed, etched and cleaned. Line-edge roughness in the resulting features is reduced.

Without wishing to be bound by theory, solvated electrons may attach themselves to the compounds in the resist altering the strength or presence of chemical bonds, likely the polymer chains and/or otherwise be stabilized by ions in the liquid. The polymer chains may then be more susceptible to being broken by the addition of energy than if the effect of the solvated electrons were not present. The EUV photons incident on the plasma-activated photoresist create photo-electrons which may in turn create secondary electrons, but fewer electrons will be needed to break the weaker bonds. Thus, the dose of EUV required may be reduced, and line-edge roughness is improved since fewer chemically amplified components are necessary.

### Example 2: Plasma-Activated Cleaning Solution Liquid

A conventional cleaning solution liquid is provided.

The cleaning solution is plasma activated via the apparatus of FIG. 1. A wafer is coated in photoresist and exposed to EUV. The exposed wafer is developed and etched. The etched wafer is cleaned with the plasma-activated cleaning solution. Efficacy of the cleaning solution is increased.

### Example 3: Plasma-Activated Developer Liquid

A developer liquid comprising TMAH (tetramethyammonium hydroxide) and a buffer solution to control pH is provided. The developer liquid is plasma activated via the apparatus of FIG. 1. A wafer is coated in photoresist and exposed to EUV. The exposed wafer is then developed via the plasma-activated developer solution. Efficacy of the developer liquid is increased leaving a more defined pattern with less line edge roughness

### Example 4: Plasma-Activated Photoresist Liquid

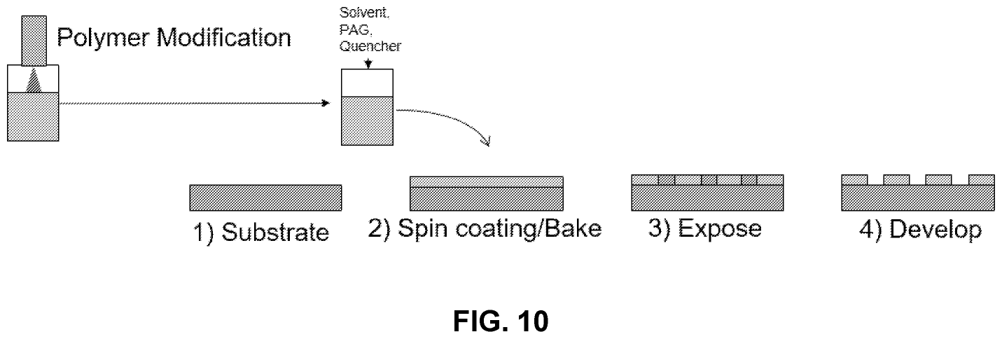

Turning now to FIG. 10, a polymer precursor liquid was plasma-activated via treatment with a plasma jet. The plasma-activated precursor liquid was then combined with solvent, a photoactive group (PAG), and a quencher to produce a plasma-activated liquid photoresist. The plasma-activated liquid photoresist was applied to a substrate, baked, exposed, and developed. In direct comparison with control experiments which replicated all conditions other than the plasma treatment, the plasma-activated photoresist liquid showed improved sensitivity to UV exposure. The amount of energy per unit area needed to produce a defined pattern was reduced.

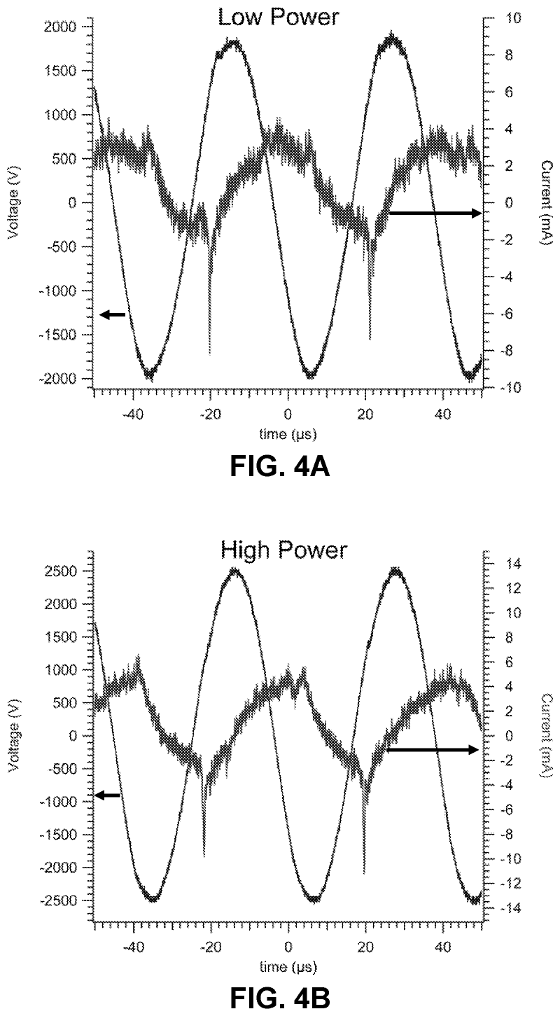

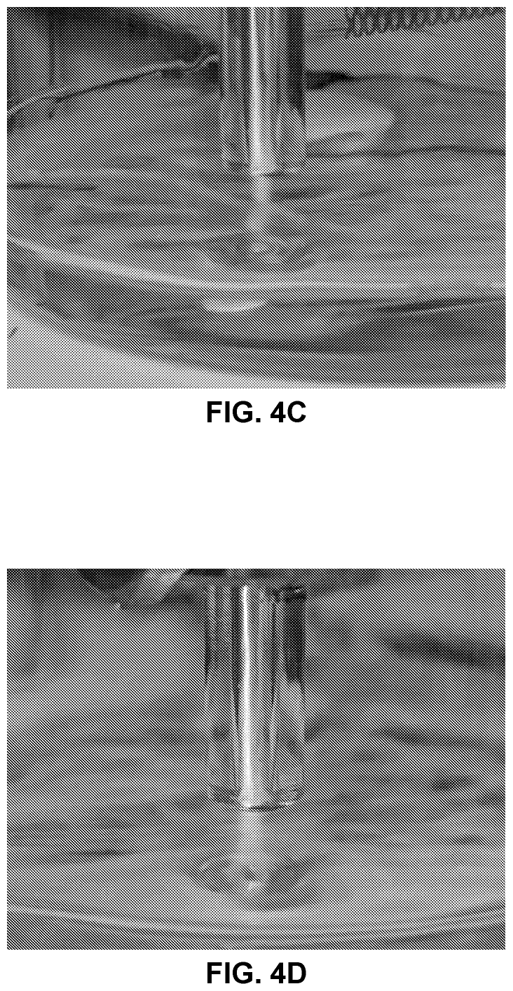

All treatments were performed with an AC remote plasma jet. Two different power settings of the plasma apparatus, “low” and “high” power were employed. The power output of the two levels is shown in FIG. 4. “Low” power is 10% of the power supply which is an average current of 1.2 mA. “High” power is 15% of the power supply output which is an average current of 1.5 mA. After samples were treated, they were exposed within 2-3 h.

A photoresist polymer precursor liquid containing organic disulfides and an additional functional group that is able to be polymerized and is based on an acrylate, along with alkyl ester that forms an acid was used. This was dissolved in a solvent comprised of glycol ethers.

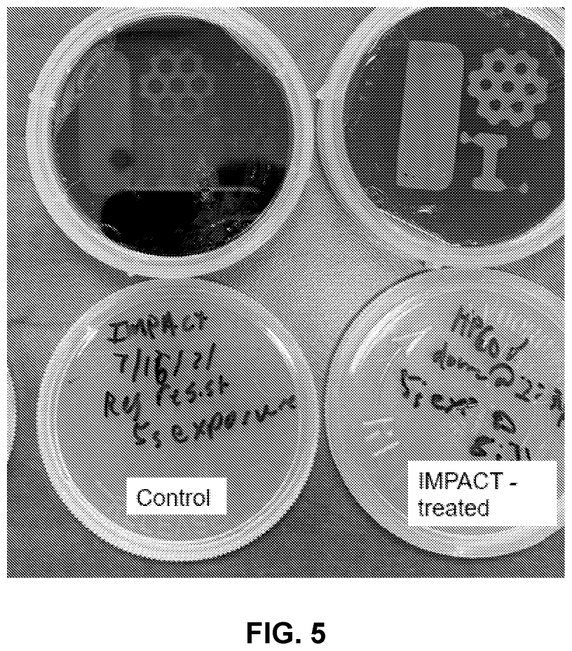

FIG. 5 demonstrates the beneficial effect of plasma activation of a photoresist liquid. Specifically, the sample on the right was prepared by plasma treating the polymer precursor liquid at “high” power for 60 min before mixing the plasma-activated polymer precursor liquid into a photoresist, coating a substrate, exposing for 5 seconds and then developing. The control sample on the left was prepared in the same manner, except there was no plasma treatment step. It appears from the side-by-side photographs that the lithography of the plasma-activated sample displays sharper edges and enhanced development as compared to the control.

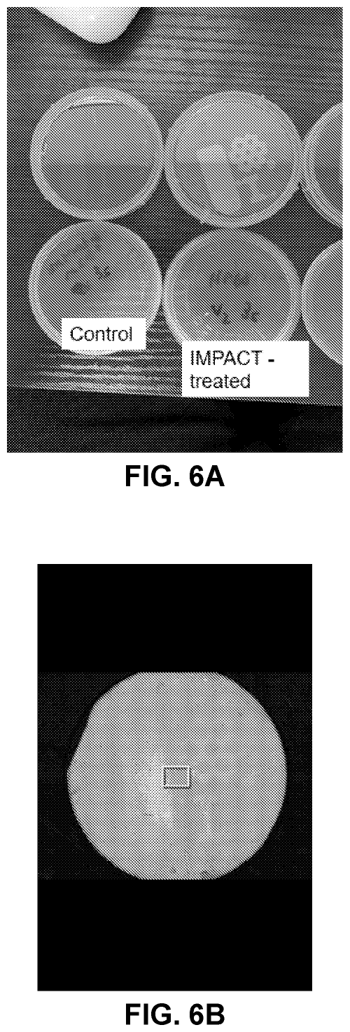

FIG. 6A shows another side by side comparison, this time with a shorter exposure time. The sample on the right was prepared by plasma treating the polymer precursor liquid for 60 min before mixing the plasma-activated polymer precursor liquid into a photoresist, coating a substrate, exposing to UV light for 3 seconds and then developing. The control sample on the left was prepared in the same manner, except there was no plasma treatment step. As can be seen, the lithography of the plasma-activated sample displays sharp edges and complete development, whereas the control has hardly developed at all.

FIG. 6B shows a second control to the experiment of FIG. 6A. Specifically, the sample in FIG. 6B was prepared as with the plasma-activated sample shown in FIG. 6A except the sample was subjected to 60 minutes of gas flow in place of the plasma activation step in order to rule out any effects of the evaporation associated with the plasma jet. As can be seen in FIG. 6B, gas flow does not improve the lithography, suggesting that it was in fact the plasma itself leading to the results of FIG. 6A.

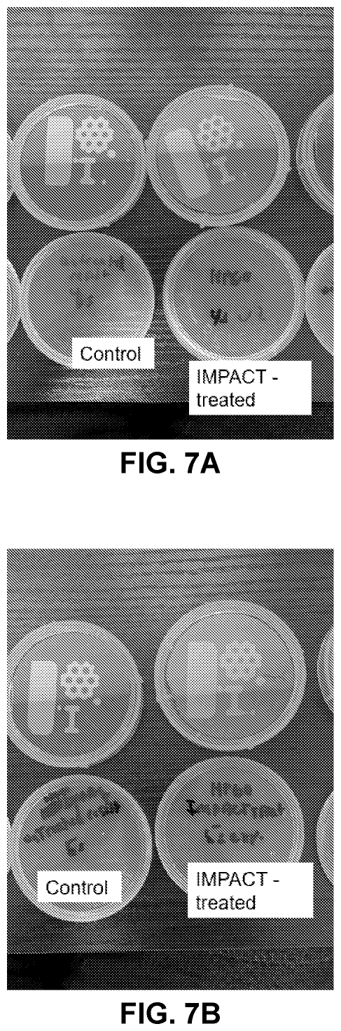

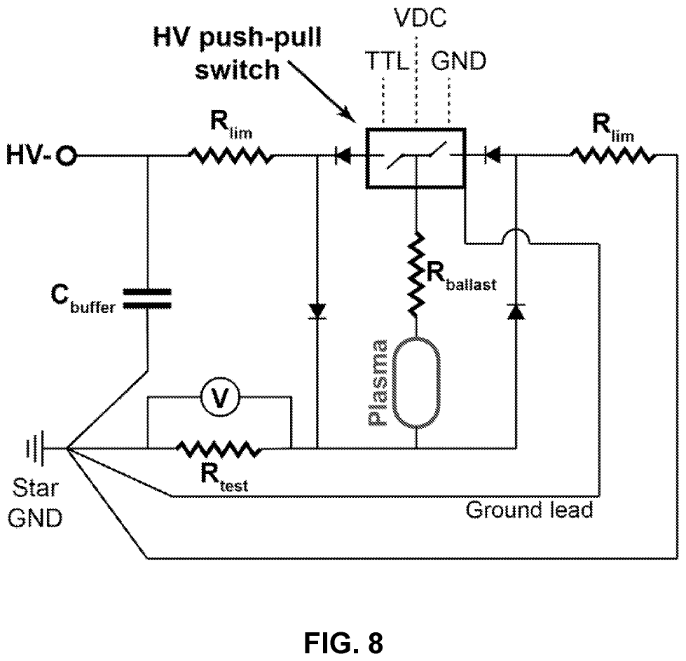

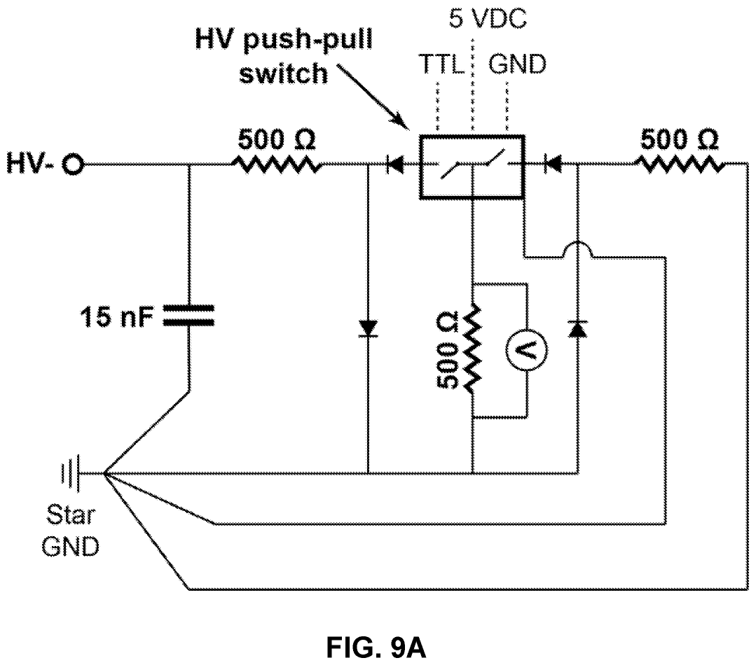

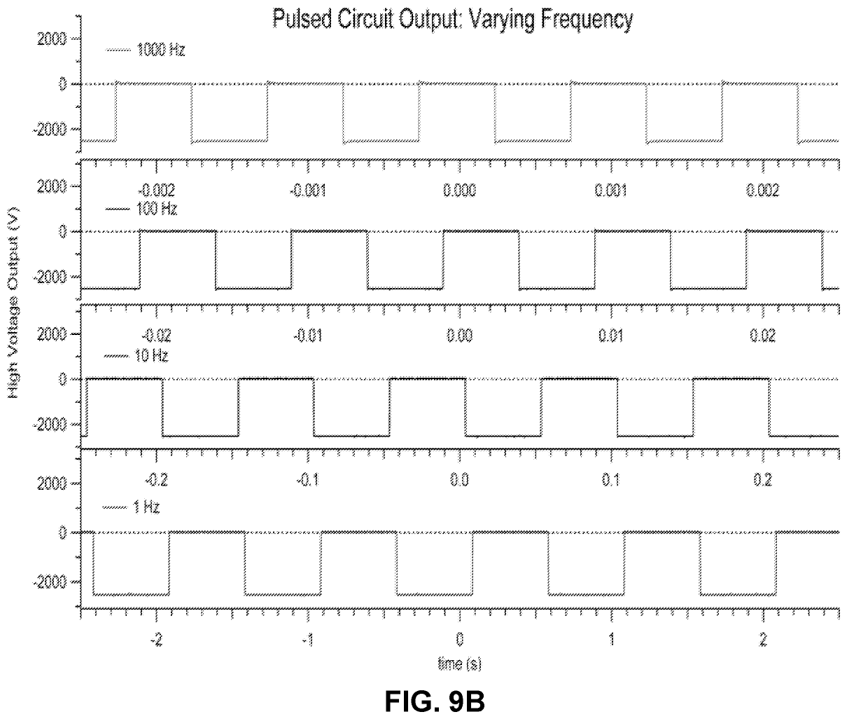

FIG. 7A shows the results of a side by side comparison identical to the experiment shown in FIG. 6A, except exposure time was 4 s. FIG. 7B shows the results of a side by side comparison identical to the experiment shown in FIG. 6A, except exposure time was 5 s.

Thus, in some embodiments, plasma activation of photo resist liquids may improve throughput of commercial integrated circuit manufacturing, as it may allow shorter development times. In other embodiments, plasma activation of photo resist liquids may improve line edge roughness of very small devices, as it may allow for lower power development radiation.

### STATEMENTS REGARDING INCORPORATION BY REFERENCE AND VARIATIONS

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, including any isomers, enantiomers, and diastereomers of the group members, are disclosed separately. When a Markush group or other grouping is used herein, all individual members of the group and all combinations and subcombinations possible of the group are intended to be individually included in the disclosure. When a compound is described herein such that a particular isomer, enantiomer or diastereomer of the compound is not specified, for example, in a formula or in a chemical name, that description is intended to include each isomers and enantiomer of the compound described individual or in any combination. Additionally, unless otherwise specified, all isotopic variants of compounds disclosed herein are intended to be encompassed by the disclosure. For example, it will be understood that any one or more hydrogens in a molecule disclosed can be replaced with deuterium or tritium. Isotopic variants of a molecule are generally useful as standards in assays for the molecule and in chemical and biological research related to the molecule or its use. Methods for making such isotopic variants are known in the art. Specific names of compounds are intended to be exemplary, as it is known that one of ordinary skill in the art can name the same compounds differently.

Certain molecules disclosed herein may contain one or more ionizable groups [groups from which a proton can be removed (e.g., —COCH) or added (e.g., amines) or which can be quaternized (e.g., amines)]. All possible ionic forms of such molecules and salts thereof are intended to be included individually in the disclosure herein. With regard to salts of the compounds herein, one of ordinary skill in the art can select from among a wide variety of available counterions those that are appropriate for preparation of salts of this invention for a given application. In specific applications, the selection of a given anion or cation for preparation of a salt may result in increased or decreased solubility of that salt.

Every device, system, formulation, combination of components, or method described or exemplified herein can be used to practice the invention, unless otherwise stated.

Whenever a range is given in the specification, for example, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter are claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

One of ordinary skill in the art will appreciate that starting materials, biological materials, reagents, synthetic methods, purification methods, analytical methods, assay methods, and biological methods other than those specifically exemplified can be employed in the practice of the invention without resort to undue experimentation. All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

We claim:

1. A plasma-activated liquid comprising:
a non-aqueous liquid medium; and
at least one reactive species produced via contacting the surface of the non-aqueous liquid medium with a plasma.

2. The plasma-activated liquid of claim 1, wherein the at least one reactive species comprises free radicals, solvated electrons, or both.

3. The plasma-activated liquid of claim 1, wherein the plasma activated liquid comprises not greater than 5 wt. % water.

4. The plasma-activated liquid of claim 1, wherein the plasma activated liquid comprises not greater than 3 wt. % water.

5. The plasma-activated liquid of claim 1, wherein the plasma activated liquid comprises not greater than 2 wt. % water.

6. The plasma-activated liquid of claim 1, wherein the plasma activated liquid comprises not greater than 1 wt. % water.

7. The plasma-activated liquid of claim 1, wherein the plasma activated liquid comprises not greater than 0.1 wt. % water.

8. The plasma-activated liquid of claim 1, wherein the plasma activated liquid comprises not greater than 0.01 wt. % water.

9. The plasma-activated liquid of claim 1, wherein the plasma activated liquid comprises not greater than 0.001 wt. % water.

10. The plasma-activated liquid of any of the preceding claims, wherein the plasma activated liquid comprises free radicals, solvated electrons, or both.

11. The plasma-activated liquid of any of the preceding claims, wherein the plasma activated liquid comprises a photolithography liquid.

12. The plasma-activated liquid of claim 11, wherein the photolithography liquid is a photoresist liquid.

13. The plasma-activated liquid of claim 11, wherein the photolithography liquid is a developer liquid.

13. The plasma-activated liquid of claim 11, wherein the photolithography liquid is a cleaning solution liquid.

14. The plasma-activated liquid of any of the preceding claims comprising a plurality of solvated molecules wherein each of the plurality of molecules comprises a carbon backbone.

15. The plasma-activated liquid of claim 14, wherein each of the plurality of molecules comprises at least one covalent bond joining an acid group, directly or indirectly, to the carbon backbone.

16. The plasma-activated liquid of any of the preceding claims comprising or more ionic species to stabilize free radicals and/or solvated electrons in the plasma-activated liquid.

17. A method of manufacturing an integrated circuit, the method comprising:
activating a photolithography liquid with a plasma; and
treating a device component with the activated photolithography liquid.

18. The method of claim 17 wherein the activating step comprises bringing the photolithography liquid into contact with a plasma.

19. The method of claims 17-18, wherein the activating step comprises creating free radicals, solvated electrons, or both in the photolithography liquid.

20. The method of claims 17-19, wherein the activating step comprises:
weakening at least one covalent bond in one or more molecules of the photolithography liquid.

21. The method of claims 17-20, wherein the activating step comprises:
weakening at least one covalent bond in each of a plurality of solvated molecules of the photolithography liquid, wherein each of the plurality of molecules comprises a carbon backbone.

22. The method of claims 18-21, wherein the at least one covalent bond joins an acid group, directly or indirectly, to the carbon backbone.

23. The method of claims 19-22, wherein the activating step comprises:
stabilizing the free radicals and/or solvated electrons via cations.

24. The method of claims 19-23, wherein the activating step comprises:
stabilizing the free radicals and/or solvated electrons via one or more functional groups supported by the carbon backbone.

25. The method of claim 24, wherein the one or more functional groups comprises cationic functional groups.

26. The method of claim 24, wherein the one or more functional groups comprises anionic functional groups.

27. The method of claims 17-26, wherein the photolithography liquid is selected from the group consisting of: a photoresist liquid, a developer liquid, and a cleaning solution liquid.

28. The method of claims 17-27, wherein the activating step occurs prior to the treating step.

29. The method of claims 17-28, wherein the treating step includes contacting the device component with activated photolithography liquid.

30. The method of claims 17-29, wherein the device component comprises a semiconductor wafer.

31. The method of claims 17-30, wherein the photolithography liquid comprises a photoresist liquid.

32. The method of claim 31, wherein the photolithography liquid comprises a positive photoresist.

33. The method of claim 31, wherein the photolithography liquid comprises a negative photoresist.

34. The method of claims 31-33, comprising:
hardening the photoresist liquid into a solid layer of photoresist on the semiconductor wafer;
wherein after the hardening step, free radicals and/or solvated electrons produced via the contacting step are trapped in the solid layer of photoresist.

35. The method of claim 34 comprising:
exposing the solid layer of photoresist to a pattern of electromagnetic radiation; and
in response to the exposing step, releasing at least some of the electrons of the trapped free radicals and/or solvated electrons, thereby cleaving covalent bonds in the solid layer of photoresist.

36. The method of claim 35, comprising:
in response to the releasing step, freeing acid groups in the solid layer of photoresist.

37. The method of claims 35-36, wherein the electromagnetic radiation comprises extreme ultraviolet radiation.

38. The method of claims 35-37, wherein the electromagnetic radiation exhibits an intensity peak in a wavelength range of 13.3 to 13.7 nm.

39. The method of claims 17-38, wherein the plasma is an atmospheric pressure plasma.

40. The method of claims 17-39, wherein the contacting step occurs in a controlled gas environment.

41. The method of claims 17-40, wherein the plasma is a plasma formed via a D.C. current.

42. The method of claims 17-40, wherein the plasma is a surface wave plasma.

43. A method of manufacturing an integrated circuit, the method comprising:
coating at least a portion of a surface device component with a photoresist liquid;
hardening the photoresist liquid into a solid layer of photoresist on the wafer;
exposing the solid layer of photoresist to a pattern of electromagnetic radiation;
contacting the photoresist with a developer liquid to develop a corresponding pattern in the photoresist;
etching the wafer to transfer the pattern from the photoresist to the oxide layer;
ashing the remaining photoresist;
cleaning the wafer with a cleaning solution liquid to remove photoresist residue from the wafer; and
performing at least one of the following steps:
activating the photoresist liquid or a component of the photoresist liquid with a plasma;
activating the developer liquid or a component of the developer liquid with a plasma;
activating the cleaning solution liquid or a component of the cleaning solution liquid with a plasma.

44. The method of claim 43, comprising activating the photoresist liquid with the plasma prior to or concomitant with the coating step.

45. The method of claims 43-44, comprising activating the developer liquid with the plasma prior to or concomitant with the contacting step.

46. The method of claims 43-45, comprising activating the cleaning solution with the plasma prior to or concomitant with the cleaning step.

47. A method of manufacturing an integrated circuit, the method comprising:
coating at least a portion of a surface device component with a photoresist liquid;
hardening the photoresist liquid into a solid layer on the wafer;
exposing the photoresist to electromagnetic radiation;
applying developer liquid to remove the exposed photoresist;
prior to or concomitant with the applying step, activating the developer liquid via a plasma thereby introducing free radicals and/or solvated electrons into the developer liquid;
etching the exposed parts of the wafer;
ashing the remaining photoresist; and
removing photoresist residue with a liquid cleaning solution.

48. A method of manufacturing an integrated circuit, the method comprising:
coating at least a portion of a surface device component with a photoresist liquid;
hardening the photoresist liquid into a solid layer on the wafer;
exposing the photoresist to electromagnetic radiation;
applying developer liquid to remove the exposed photoresist;
etching the exposed parts of the wafer;
ashing the remaining photoresist;
removing photoresist residue with a liquid cleaning solution; and
prior to or concomitant with the removing step, activating the liquid cleaning solution via a plasma thereby introducing free radicals and/or solvated electrons into the liquid cleaning solution.

49. The method of claim 48, comprising:
prior to the removing step, mixing a first component with a second component to form the liquid cleaning solution.

50. The method of claim 49, wherein the activating step comprises:
prior to the mixing step, activating the first component with a plasma.

51. A method of manufacturing an integrated circuit, the method comprising:
coating at least a portion of a surface device component with a photoresist liquid;
hardening the photoresist liquid into a solid layer on the wafer;
exposing the photoresist to electromagnetic radiation;
applying developer liquid to remove the exposed photoresist;
etching the exposed parts of the wafer;
ashing the remaining photoresist;
removing photoresist residue with a liquid cleaning solution; and
prior to or concomitant with the coating step, activating the photoresist liquid, or a component of the photoresist liquid via a plasma thereby introducing free radicals and/or solvated electrons into the photoresist liquid or a component of the photoresist liquid.

52. A method of manufacturing an integrated circuit, the method comprising:
coating at least a portion of a surface device component with a photoresist liquid;
hardening the photoresist liquid into a solid layer on the wafer;
exposing the photoresist to electromagnetic radiation;
applying developer liquid to remove the exposed photoresist;
etching the exposed parts of the wafer;
ashing the remaining photoresist;
removing photoresist residue with a liquid cleaning solution; and
prior to or concomitant with the applying step, activating the developer liquid or a component of the developer liquid via a plasma thereby introducing free radicals and/or solvated electrons into the developer liquid or a component of the developer liquid.

53. A method of manufacturing an integrated circuit, the method comprising:
coating at least a portion of a surface device component with a photoresist liquid;
hardening the photoresist liquid into a solid layer on the wafer;
exposing the photoresist to electromagnetic radiation;
applying developer liquid to remove the exposed photoresist;
etching the exposed parts of the wafer;
ashing the remaining photoresist;
removing photoresist residue with a liquid cleaning solution; and
prior to or concomitant with the removing step, activating the liquid cleaning solution or a component of the liquid cleaning solution via a plasma thereby introducing free radicals and/or solvated electrons into the liquid cleaning solution or a component of the liquid cleaning solution.
